(19) United States
(12) Patent Application Publication
(10) Pub. No.: US 2025/0355239 A1
(43) Pub. Date: Nov. 20, 2025

(54) VIBRATION MODULE AND OPTICAL DEFLECTOR

(71) Applicant: Panasonic Intellectual Property Management Co., Ltd., Osaka (JP)

(72) Inventors: DAISUKE WAKUDA, Kyoto (JP); KENSUKE MIHARA, Osaka (JP)

(21) Appl. No.: 19/290,013

(22) Filed: Aug. 4, 2025

Related U.S. Application Data
(63) Continuation of application No. PCT/JP2024/004124, filed on Feb. 7, 2024.

(30) Foreign Application Priority Data
Feb. 24, 2023 (JP) 2023-027427

(51) Int. Cl. G02B 26/08; G02B 26/10; H02N 2/10

(52) U.S. Cl. CPC G02B 26/0858; G02B 26/101; H02N 2/108

(57) ABSTRACT

A vibration module and an optical deflector can suppress a change in deflection angle of a movable part due to a change in static displacement of a piezoelectric body associated with a temperature change. The vibration module includes a drive element and a substrate supporting the drive element. The drive element includes a movable part, a drive unit that includes a piezoelectric body as a drive source and rotates the movable part about a rotation axis, and a fixing part that supports the movable part and the drive unit and is bonded to the substrate. The fixing part is bonded to the substrate at a plurality of portions discrete from each other with an adhesive whose elastic modulus decreases as a temperature rises, and the plurality of portions include a portion corresponding to an antinode of vibration generated in the fixing part when the movable part is resonantly driven.

### BACKGROUND

### 1. Technical Field

The present disclosure relates to a vibration module that rotates a movable part about a rotation axis, and an optical deflector including the vibration module.

### 2. Description of the Related Art

In recent years, a drive element that rotates a movable part using a micro electro mechanical system (MEMS) technology has been developed. In this type of drive element, a reflective surface is disposed on the movable part, and light entering the reflective surface can be scanned at a predetermined deflection angle. This type of drive element is mounted on an image display device such as a head-up display or a head-mounted display. This type of drive element can also be used for a laser radar or the like that detects an object using laser light.

PTL 1 shown below describes a drive element of a type in which a movable part is rotated by a so-called tuning fork vibrator. In this drive element, a piezoelectric body is disposed in each of a pair of arms extending along a rotation axis. When AC voltages having phases different from each other by 180° (opposite phases) are applied to the piezoelectric bodies, the pair of arms expand and contract in opposite directions. As a result, the movable part rotates about a rotation axis, and accordingly, the reflective surface disposed on the movable part rotates. The tuning fork vibrator is connected to a frame-shaped fixing part via a connecting part extending along the rotation axis.

### CITATION LIST

### Patent Literature

PTL 1: Japanese Patent Publication No. 5045470

### SUMMARY

In the drive element having the above configuration, the piezoelectric body is driven such that the movable part repeatedly rotates at a natural resonance frequency. However, in the piezoelectric body, a driving amount (static displacement) when a constant voltage is applied changes according to a temperature change. Thus, even when the same drive voltage is applied to the piezoelectric body, the deflection angle of the movable part during resonance driving changes according to the temperature.

In view of such a problem, an object of the present disclosure is to provide a vibration module and an optical deflector capable of suppressing a change in the deflection angle of a movable part due to a change in static displacement of a piezoelectric body associated with a temperature change.

A first aspect of the present disclosure relates to a vibration module. A vibration module according to this aspect includes a drive element and a substrate supporting the drive element. The drive element includes a movable part, a drive unit that includes a piezoelectric body as a drive source and rotates the movable part about a rotation axis, and a fixing part that supports the movable part and the drive unit and is bonded to the substrate. The fixing part is bonded to the substrate at a plurality of portions discrete from each other with an adhesive whose elastic modulus decreases as a temperature rises, and the plurality of portions include a portion corresponding to an antinode of vibration generated in the fixing part when the movable part is resonantly driven.

In the vibration module according to the present aspect, the elastic modulus of the adhesive decreases as the temperature rises. Thus, the portions corresponding to antinodes of vibration of the fixing part bonded by the adhesive easily vibrate as the temperature rises. Thus, as the temperature rises, the loss of vibration energy in the portions corresponding to antinodes of vibration increases, and the Q factor as the vibration module decreases. As a result, the increase in the static displacement and the decrease in the Q factor associated with the temperature rise act in opposite directions to each other, and as a result, the output of the vibration module is suppressed from changing with the temperature change. Therefore, it is possible to suppress a change in the deflection angle of the movable part based on a temperature change.

A second aspect of the present disclosure relates to an optical deflector. An optical deflector according to this aspect includes the vibration module according to the first aspect and a reflective surface disposed on the movable part.

Since the optical deflector according to the present aspect includes the vibration module according to the above aspect, it is possible to suppress a change in deflection angle of the movable part and the reflective surface based on a temperature change. Thus, the light entering the reflective surface can be stably deflected at a predetermined deflection angle, and scanning with the light can be performed at the predetermined deflection angle.

As described above, according to the vibration module and the optical deflector of the present disclosure, it is possible to provide a vibration module and an optical deflector capable of suppressing a change in the deflection angle of a movable part due to a change in static displacement of a piezoelectric body based on a temperature change.

Effects and meanings of the disclosure according to the present disclosure (hereinafter, referred to as the present disclosure) will be more apparent from the following description of exemplary embodiments. The exemplary embodiments shown below are merely examples when the present disclosure is implemented, and the present disclosure is not limited to the description in the following exemplary embodiments at all.

### BRIEF DESCRIPTION OF THE DRAWINGS

FIG. 1 is a perspective view illustrating a configuration of a drive element according to an exemplary embodiment;

FIG. 2 is a perspective view of the drive element according to the exemplary embodiment as viewed from a lower surface side;

FIG. 3 is a plan view illustrating a configuration of a vibration module according to the exemplary embodiment;

FIG. 4 is a perspective view illustrating an example of a usage mode of the vibration module (optical deflector) according to the exemplary embodiment;

FIG. 5 is a graph illustrating a measurement result obtained by measuring the static displacement of a piezoelectric body for each temperature according to the exemplary embodiment;

FIG. 6 is a diagram illustrating a simulation result obtained by simulating the vibration generated in the fixing part when the movable part is driven resonantly according to the exemplary embodiment;

FIG. 7A is a plan view illustrating a method for bonding the drive element to a substrate according to the exemplary embodiment;

FIG. 7B is a plan view illustrating a method for bonding the drive element to a substrate according to the exemplary embodiment;

FIG. 8A is a view illustrating a measurement position when the drive element bonded by the bonding method illustrated in FIGS. 7A and 7B according to the exemplary embodiment is actually resonantly driven;

FIG. 8B is a diagram illustrating a verification example in which the vibration generated in the fixing part is measured when the drive element bonded by the bonding method illustrated in FIGS. 7A and 7B is actually resonantly driven according to the exemplary embodiment;

FIG. 9A is a graph schematically illustrating an ideal relationship between a change in static displacement of the vibration module accompanying a temperature change and a change in a Q factor of the vibration module associated with the temperature change according to the exemplary embodiment;

FIG. 9B is a graph schematically illustrating temperature characteristics of deflection angles of the movable part and the reflective surface during resonance driving when the static displacement and the Q factor are in the ideal relationship as illustrated in FIG. 9A according to the exemplary embodiment;

FIG. 10A is a plan view illustrating a method for bonding a drive element to a substrate according to a first modification;

FIG. 10B is a plan view illustrating the method for bonding the drive element to the substrate according to the first modification;

FIG. 11A is a plan view illustrating a method for bonding a drive element to a substrate according to a second modification; and

FIG. 11B is a plan view illustrating the method for bonding the drive element to the substrate according to the second modification.

### DETAILED DESCRIPTIONS

Hereinafter, an exemplary embodiment of the present disclosure will be described with reference to the drawings. For the sake of convenience, X, Y, and Z axes perpendicular to each other are added to the drawings. The Y-axis directions are directions parallel to a rotation axis of a drive element, and the Z-axis directions are thickness directions of the drive element.

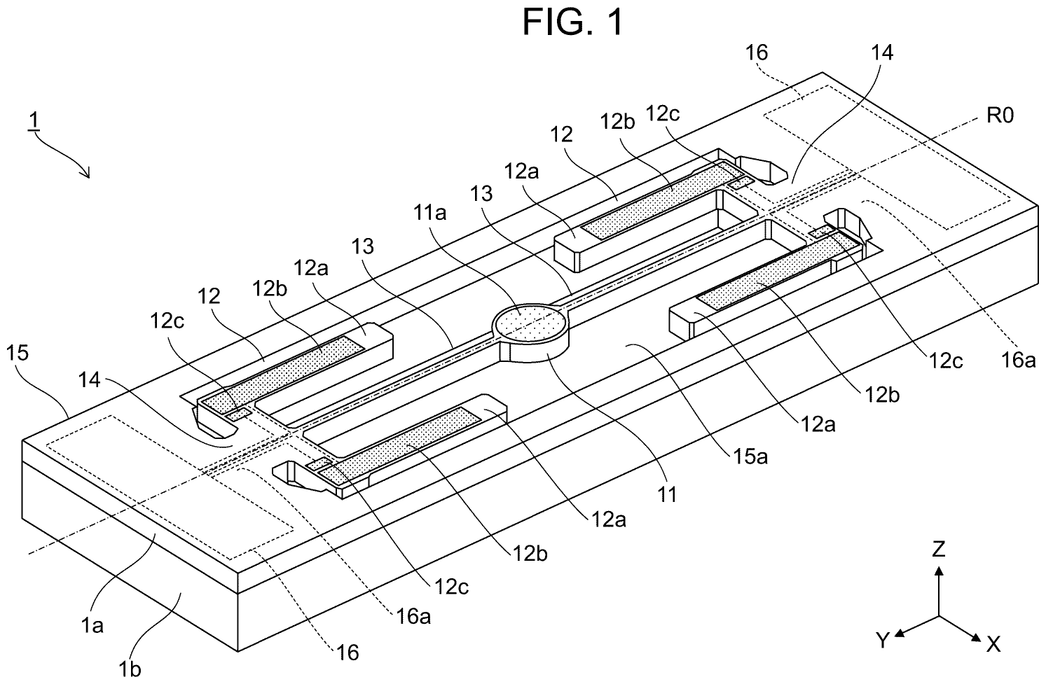

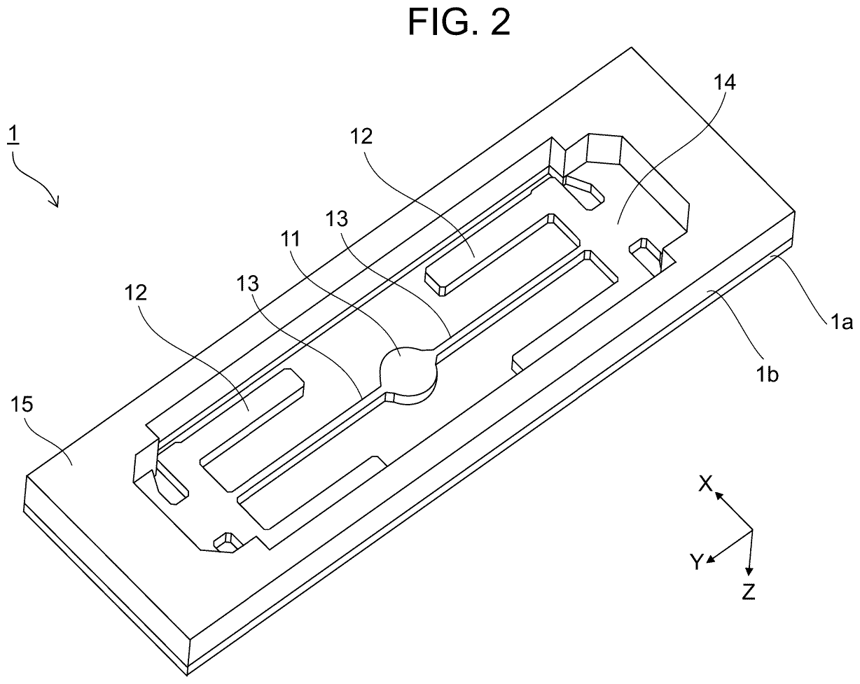

FIG. 1 is a perspective view illustrating a configuration of drive element 1. FIG. 2 is a perspective view of drive element 1 as viewed from a lower surface side (negative side of the Z axis).

Drive element 1 includes movable part 11, two drive units 12, two torsion parts 13, two supports 14, and a fixing part 15. Drive element 1 has a rectangular outline in plan view. Drive element 1 has a symmetrical shape in the Y-axis directions and a symmetrical shape in the X-axis directions.

Movable part 11 is supported by fixing part 15 via two torsion parts 13 and two supports 14 so as to be rotatable about rotation axis R0. Rotation axis R0 extends in parallel with the length directions (Y-axis directions) of drive element 1 at an intermediate position in the width directions (X-axis directions) of drive element 1. Reflective surface 11a is formed on an upper surface (surface on the positive side of the Z axis) of movable part 11. Reflective surface 11a is formed by stacking a high reflectance material (for example, a metal such as gold, silver, copper, or aluminum, a metal compound, silicon dioxide, titanium dioxide, or the like) on the upper surface of movable part 11. Reflective surface 11a may be made up of a dielectric material multilayer film. Alternatively, the upper surface of movable part 11 may constitute reflective surface 11a. In this case, the upper surface of movable part 11 may be mirror-finished to form the reflective surface.

Two torsion parts 13 have a beam shape extending along rotation axis R0, and are disposed so as to sandwich movable part 11 in the Y-axis directions. One end of torsion part 13 on the positive side of the Y axis is connected to the side surface on the positive side of the Y axis of movable part 11, and the other end is connected to support 14 on the positive side of the Y axis. One end of torsion part 13 on the negative side of the Y axis is connected to the side surface on the negative side of the Y axis of movable part 11, and the other end is connected to support 14 on the negative side of the Y axis.

Two supports 14 each have a plate-like shape extending along the rotation axis, and they connect two torsion parts 13 to fixing part 15, respectively.

Two drive units 12 each include piezoelectric body 12b as a drive source, and they rotate movable part 11 about rotation axis R0. Each of two drive units 12 is made up of a tuning fork vibrator. That is, two tuning fork vibrators are disposed in opposite directions along rotation axis R0, thereby forming two drive units 12.

Each drive unit 12 includes a pair of arms 12a extending from support 14 in an L shape. Piezoelectric body 12b for driving movable part 11 is disposed on an upper surface of a portion extending in the Y-axis directions of each arm 12a. Piezoelectric body 12c for detecting a vibration state of arm 12a is disposed near the root of each arm 12a.

Each of piezoelectric bodies 12b and 12c has a stacked structure in which electrode layers are disposed above and below a piezoelectric thin film having a predetermined thickness. The piezoelectric thin film is made of, for example, a piezoelectric material having a high piezoelectric constant such as lead zirconate titanate (PZT). The material of the piezoelectric thin film is not limited to PZT, and may be a piezoelectric material having another composition. The electrode is made of a material having low electric resistance and high heat resistance, such as platinum (Pt). Piezoelectric bodies 12b and 12c are disposed on the upper surfaces of the respective parts by forming a layer structure including the piezoelectric thin film and upper and lower electrodes on the upper surface of arm 12a using a sputtering method or the like.

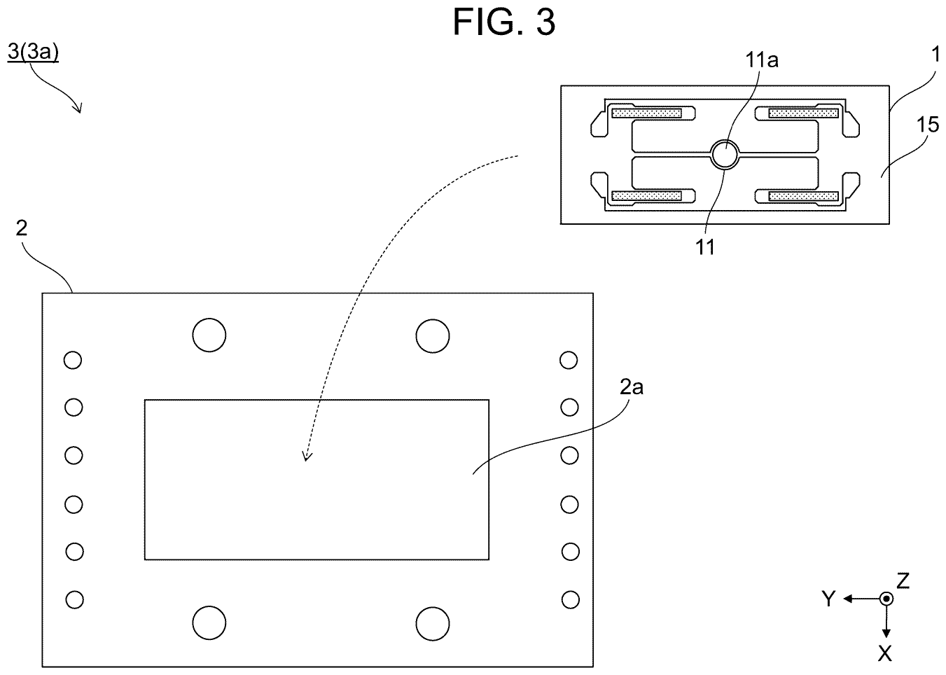

Fixing part 15 has a frame shape having a rectangular outline in plan view. The outline of fixing part 15 forms an outline of drive element 1. Fixing part 15 supports movable part 11, drive unit 12, and torsion part 13 via two supports 14. Movable part 11 is bonded to substrate 2 (see FIG. 3) as described later.

Two terminal parts 16 are disposed on the upper surface of fixing part 15. Two piezoelectric bodies 12b and two piezoelectric bodies 12c on the positive side of the Y axis are connected to terminal part 16 on the positive side of the Y axis via wiring 16a. Two piezoelectric bodies 12b and two piezoelectric bodies 12c on the negative side of the Y axis are connected to terminal part 16 on the negative side of the Y axis via wiring 16a. On the upper surface of terminal part 16, a plurality of terminals (not illustrated) each connected to the positive electrode of the corresponding piezoelectric body and terminals (not illustrated) for connecting the negative electrodes of the piezoelectric bodies to the ground are disposed. These terminals are connected to a drive circuit on substrate 2 (see FIG. 3) side through wire bonding.

Drive element 1 is configured by stacking material layer 1b on a lower surface of base material 1a having a predetermined thickness. Material layer 1b is stacked only in a region corresponding to fixing part 15. This increases the mechanical strength of fixing part 15. The material of material layer 1b may be a material different from base material 1a, or may be the same material as base material 1a.

Alternatively, drive element 1 is formed by cutting material layer 1b through etching or the like so as to leave a region corresponding to fixing part 15 from an integrated structure made up of base material 1a and material layer 1b having a predetermined thickness. This increases the mechanical strength of fixing part 15. The material of material layer 1b may be a material different from base material 1a, or may be the same material as base material 1a.

Base material 1a has the same outline as that of drive element 1 in plan view and has a constant thickness. Reflective surface 11a and piezoelectric bodies 12b and 12c are disposed in corresponding regions on the upper surface of base material 1a. Base material 1a is cut by etching or the like so as to leave movable part 11, drive unit 12, torsion part 13, and support 14, and movable part 11, drive unit 12, torsion part 13, and support 14 are formed on base material 1a. The range of base material 1a other than movable part 11, drive unit 12, torsion part 13, and support 14 is opening 15a penetrating vertically.

Base material 1a is integrally formed of, for example, silicon. The material constituting base material 1a is not limited to silicon, and may be another material. The material constituting base material 1a is preferably a material having high mechanical strength and high Young's modulus. The same applies to the material of material layer 1b.

At the time of driving drive element 1, an AC voltage for resonantly driving movable part 11 at the natural frequency (resonance frequency) of drive element 1 is applied to four piezoelectric bodies 12b. As a result, each of four piezoelectric bodies 12b is deformed by the inverse piezoelectric effect. At this time, the AC voltages applied to two piezoelectric bodies 12b arranged in the Y-axis directions are set to the same phase, and the AC voltages applied to two piezoelectric bodies 12b arranged in the X-axis directions are set to opposite phases. As a result, the deformation direction (amplitude direction) of two piezoelectric bodies 12b on the positive side of the X axis and the deformation direction (amplitude direction) of piezoelectric body 12b on the negative side of the X axis are in opposite directions. In this manner, arm 12a is deformed because of the deformation of four piezoelectric bodies 12b, whereby movable part 11 is driven to resonate at a predetermined resonance frequency around rotation axis R0 via two torsion parts 13.

In four piezoelectric bodies 12c for vibration detection, a current is generated because of the piezoelectric effect according to the deformation of corresponding arm 12a. Thus, the vibration state of arm 12a can be monitored from this current. In the drive circuit on substrate 2 side, the AC voltage applied to each piezoelectric body 12b is controlled using this current so that the amplitude, frequency, and phase of each arm 12a converge to each target value. As a result, movable part 11 and reflective surface 11a rotate at a target resonance frequency and deflection angle.

FIG. 3 is a plan view illustrating a configuration of vibration module 3.

Vibration module 3 includes above-described drive element 1 and substrate 2 on which drive element 1 is installed. Substrate 2 has a rectangular shape in plan view. As substrate 2, for example, a glass epoxy substrate, a paper phenol substrate, a ceramic substrate, a glass substrate, or the like can be used.

Bottomed recess 2a into which drive element 1 is fitted is formed in substrate 2. Recess 2a has a rectangular shape in plan view and is slightly larger than the outline of drive element 1. The depth of recess 2a is constant and is substantially the same as the thickness of drive element 1. As described above, the drive circuit for driving drive element 1 is mounted on substrate 2.

Drive element 1 is fitted into recess 2a and mounted to substrate 2. Specifically, an adhesive is applied between the back surface of fixing part 15 of drive element 1 and the bottom surface of recess 2a, and fixing part 15 is bonded to recess 2a. Thus, drive element 1 is mounted on substrate 2. Thereafter, as described above, the drive circuit on substrate 2 side and each terminal of terminal part 16 of drive element 1 are connected through wire bonding. The assembly of vibration module 3 is thus completed.

In the present exemplary embodiment, reflective surface 11a is formed on the upper surface of movable part 11. Thus, vibration module 3 constitutes optical deflector 3a that deflects light entering reflective surface 11a in accordance with the driving of movable part 11.

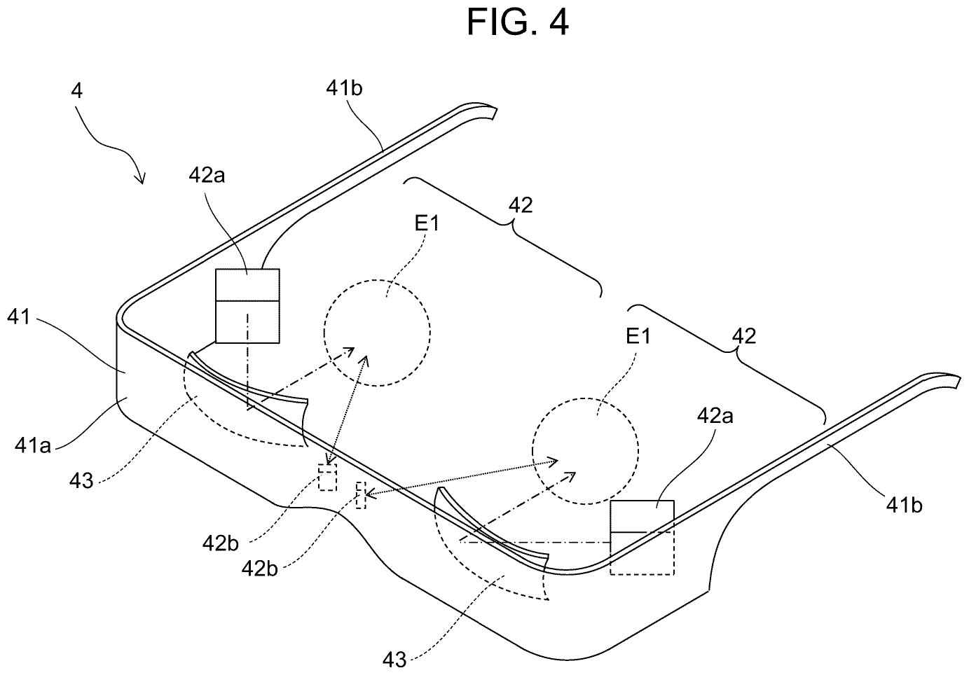

FIG. 4 is a perspective view illustrating an example of a usage mode of vibration module 3 (optical deflector 3a) of FIG. 3.

In the example of FIG. 4, vibration module 3 (optical deflector 3a) is used for a head-mounted display. Examples of the head-mounted display include AR glasses, AR goggles, VR glasses, and VR goggles. The head-mounted display of FIG. 4 is AR glasses. The usage mode of FIG. 4 is an example, and vibration module 3 (optical deflector) can also be used for an in-vehicle head-up display or the like.

AR glasses 4 include frame 41, a pair of image generation units 42, and a pair of mirrors 43. AR glasses 4 are worn on the head of a user like general glasses.

Frame 41 holds the pair of image generation units 42 and the pair of mirrors 43. Frame 41 has the front surface part 41a and a pair of supports 41b. The pair of supports 41b extends rearward from the right end and the left end of front surface part 41a. When frame 41 is worn by the user, front surface part 41a is positioned in front of the pair of eyes E1 of the user. Frame 41 is made of a transparent material. Frame 41 may be made of an opaque material.

The pair of image generation units 42 is disposed symmetrically in the width directions of AR glasses 4. Image generation unit 42 generates an image at eye E1 of the user wearing AR glasses 4 on the head.

Mirror 43 is a mirror having a concave reflective surface, and is installed on an inner surface of front surface part 41a of frame 41. Mirror 43 substantially totally reflects light projected from corresponding projector 42a and guides the light to eye E1 of the user.

Image generation unit 42 includes projector 42a and detector 42b.

Projector 42a is installed on the inner surface of support 41b. Projector 42a projects light modulated by a video signal to corresponding mirror 43. The light from projector 42a reflected by mirror 43 is applied to the central fovea located at the center of the retina in eye E1. As a result, the user can visually grasp the frame image generated by image generation unit 42. The pair of detectors 42b is installed on the inner surface of front surface part 41a between the pair of mirrors 43. Detector 42b is used to detect the line of sight of the user.

Projector 42a scans the retina in eye E1 with the light modulated by the video signal in a horizontal direction and a vertical direction. As a result, the frame image is projected onto the retina. At this time, projector 42a changes the light scanning range so that the frame image is positioned at a position corresponding to the line of sight detected by detector 42b. Scanning in the horizontal direction is faster in several stages than scanning in the vertical direction.

Vibration module 3 (optical deflector 3a) in FIG. 3 is used for horizontal scanning of the light modulated by the video signal. Since scanning in the vertical direction is performed at a low speed, a low-speed optical deflector is used for this scanning. For example, an optical deflector (vibration module) using a meander type drive element can be used for scanning in the vertical direction.

As the light source, for example, three light sources that respectively emit red, green, and blue light are used. The emission intensity of each light source is modulated by the video signal. The light from these light sources is formed into parallel light by a collimator lens and then integrated by two dichroic mirrors. The light thus integrated enters reflective surface 11a of vibration module 3 (optical deflector 3a) in FIG. 3. When movable part 11 is resonantly driven, the light repeatedly performs scanning in the horizontal direction. The optical deflector in the subsequent stage causes the light reflected by reflective surface 11a to perform scanning in the vertical direction. In this manner, the frame image is projected on the retina in eye E1.

Meanwhile, in drive element 1 having the above configuration, as described above, four piezoelectric bodies 12b are driven such that movable part 11 repeatedly rotates at a natural resonance frequency. However, in piezoelectric body 12b, a driving amount (static displacement) when a constant voltage is applied changes according to the temperature. Thus, even when the same drive voltage (AC voltage) is applied to piezoelectric body 12b, the rotation amount of movable part 11 at the time of resonance driving changes according to the temperature.

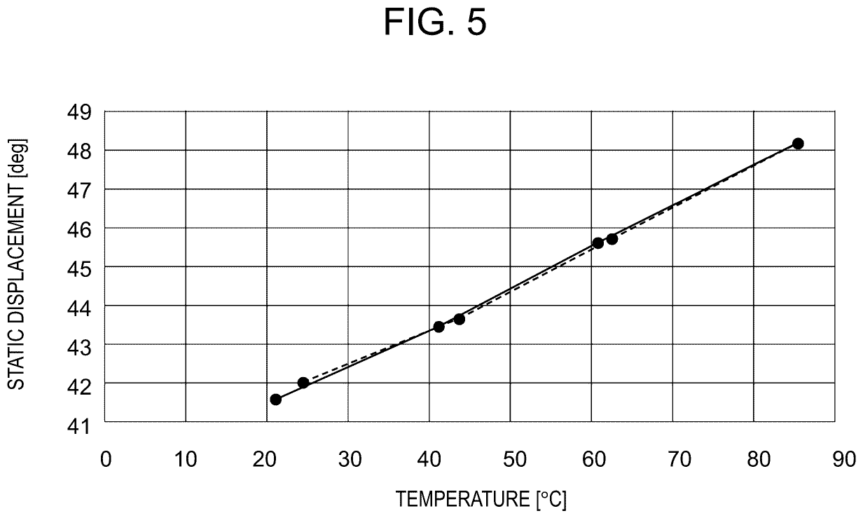

FIG. 5 is a graph illustrating a measurement result obtained by measuring the static displacement of piezoelectric body 12b for each temperature.

Here, a MEMS mirror for static displacement measurement formed using a piezoelectric body having the same configuration as that of piezoelectric body 12b was driven at a low speed (static displacement) to measure the optical full-width angle of the movable part. The drive signal was a 60 Hz Sin wave (AC voltage). The MEMS mirror was installed in a thermostatic bath with a window, and laser light was made incident on the mirror through the window to scan a detection surface with the laser light. The rotation angle (optical full-width angle) of the movable part was measured from the scanning length at this time. In FIG. 5, “deg” represents the degree (°) of the angle. That is, 1 deg=10.

With this measurement method, the temperature in the thermostatic bath was changed, and the optical full-width angle at each temperature was measured as the static displacement of piezoelectric body 12b. In addition, the temperature in the thermostatic bath was raised from room temperature to 85° C. and then lowered to around room temperature.

In FIG. 5, the solid line indicates the measurement result of the static displacement amount when the temperature in the thermostatic bath is raised from room temperature to 85° C., and the broken line indicates the measurement result when the temperature in the thermostatic bath is lowered from 85° C. to around room temperature. A black circle plot in FIG. 5 indicates a measurement point. The solid line connects the measurement results of adjacent measurement points at the time of temperature rise, and the broken line connects the measurement results of the adjacent measurement points at the time of temperature decrease.

As illustrated in FIG. 5, the static displacement of piezoelectric body 12b increased as the temperature rises, and decreased as the temperature decreases. In addition, the static displacement changed with substantially the same tendency between when the temperature is raised and when the temperature is lowered. From this, it has been confirmed that the static displacement amounts are also substantially the same when the environmental temperature of piezoelectric body 12b is the same between when the temperature is raised and when the temperature is lowered.

Due to such characteristics of piezoelectric body 12b, the deflection angle (amplitude amount in the rotation direction) at the time of resonance driving of movable part 11 and reflective surface 11a changes according to the environmental temperature of drive element 1. That is, even when movable part 11 is caused to resonate with the AC voltage of the same magnitude, the deflection angle of movable part 11 and reflective surface 11a increases when the environmental temperature is raised. Thus, vibration module 3 is required to have a robust configuration in which the deflection angles of movable part 11 and reflective surface 11a hardly change even when the environmental temperature changes.

Thus, in the present exemplary embodiment, the method for bonding drive element 1 to substrate 2 is improved so as to suppress the influence of the static displacement associated with the temperature change.

In general, the output in vibration module 3, that is, the deflection angle of movable part 11 at the time of resonance driving is determined by a value obtained by multiplying the static displacement by the Q factor of vibration module 3. Thus, when the static displacement increases in response to the temperature rise as described above, the Q factor of vibration module 3 is decreased in response to the temperature rise, whereby the output fluctuation of vibration module 3 associated with the temperature change can be suppressed. Preferably, by changing the Q factor so that the value obtained by multiplying the static displacement and the Q value becomes constant, the influence of the change in the static displacement due to the temperature change can be substantially eliminated even when the temperature of vibration module 3 changes.

In the present exemplary embodiment, the Q factor of vibration module 3 is decreased in accordance with the temperature rise with the characteristics of the adhesive for bonding fixing part 15 of drive element 1 and substrate 2 and the method for disposing the adhesive.

That is, conventionally, the adhesive has been uniformly applied to the entire lower surface of fixing part 15, and fixing part 15 has been bonded to recess 2a of substrate 2. On the other hand, in the present exemplary embodiment, the lower surface of fixing part 15 is bonded to recess 2a of substrate 2 with an adhesive at a plurality of portions discrete from each other. Here, the plurality of portions to which the adhesive is applied include portions corresponding to antinodes of vibration generated in fixing part 15 at the time of resonance driving of movable part 11. As the adhesive, an adhesive whose elastic modulus decreases as the temperature rises is used.

In this manner, when the portions corresponding to antinodes of vibration generated in fixing part 15 at the time of the resonance driving of movable part 11 are bonded with the adhesive whose elastic modulus decreases as the temperature rises, the adhesive at the antinode portions becomes soft as the temperature rises, and the vibration of the antinode portions increases. As a result, a loss occurs in the vibration energy, and the Q factor of vibration module 3 decreases. Then, the Q factor of vibration module 3 can be lowered as the temperature rises, and as a result, the influence of the static displacement due to the temperature change can be suppressed as described above.

Here, it is sufficient that the decrease in the elastic modulus of the adhesive associated with the temperature rise occurs at least in a temperature range assumed in the use environment of vibration module 3. For example, for the adhesive, adhesives containing an epoxy resin, a silicon resin, an acrylic resin, and a urethane resin as main components can be used. Preferably, an adhesive containing a modified silicon resin represented by a silicon resin, a urethane resin, and a silicon-modified epoxy resin, which have a small elastic modulus after curing and a large temperature change in elastic modulus, is used. The elastic modulus may be adjusted by mixing a filler into the resin. An adhesive having a characteristic capable of further suppressing the influence of the static displacement described above may be selected.

The thickness of the adhesive may be set to a thickness that allows the adhered portions corresponding to antinodes of vibration to appropriately vibrate at each temperature. A gap corresponding to the thickness of the adhesive is generated in a range of the back surface of fixing part 15, the range not being bonded with the adhesive.

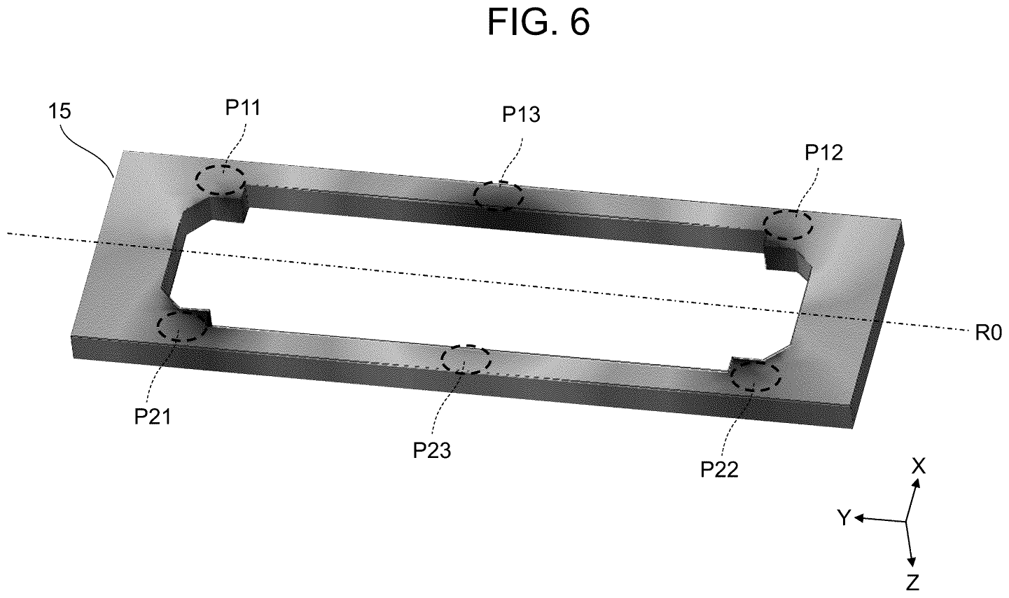

FIG. 6 is a diagram illustrating a simulation result obtained by simulating the vibration in the Z-axis direction generated in fixing part 15 when movable part 11 is resonantly driven.

For convenience, FIG. 6 illustrates only the configuration of fixing part 15. In FIG. 6, the closer to black, the larger the vibration, and the closer to white, the smaller the vibration. In FIG. 6, the vibration is large in portions P11 to P13 and P21 to P23 surrounded by broken line circles. That is, these portions P11 to P13 and P21 to P23 correspond to portions corresponding to antinodes of vibration. Thus, these portions P11 to P13 and P21 to P23 are discretely bonded to substrate 2 by the above-described adhesive, and thus, the Q factor of vibration module 3 can be reduced as the temperature rises.

When the entire range of the lower surface of fixing part 15 is uniformly bonded to substrate 2 with an adhesive like a conventional technology, the vibration of the portions corresponding to antinodes of vibration is limited because of the bonding of a portion other than the antinode portions, and thus the antinode portions are less likely to smoothly vibrate. For this reason, even when the temperature of vibration module 3 is increased, the vibration of the antinode portions hardly changes greatly, and the energy loss due to the vibration of the antinode hardly occurs. Thus, it is difficult to reduce the Q factor of vibration module 3 as the temperature rises.

On the other hand, in the present exemplary embodiment, as described above, portions P11 to P13 and P21 to P23 corresponding to antinodes of vibration are discretely bonded to recess 2a of substrate 2 by the above-described adhesive, and thus, it is possible to increase the vibration of the portions corresponding to antinodes of vibration as the temperature rises. Thus, the Q factor of vibration module 3 can be effectively reduced as the temperature rises, and as a result, the influence of the static displacement can be effectively suppressed.

All of six antinode portions P11 to P13 and P21 to P22 illustrated in FIG. 6 do not have to be bonded to substrate 2 by the adhesive. For example, intermediate portions P13 and P23 do not have to be provided with the adhesive, and portions P11, P12, P21, and P22 near the four corners may be bonded to substrate 2 with the adhesive.

However, it is preferable that portions constituting a pair symmetrical with respect to rotation axis R0 (portion P11 and portion P21, portion P12 and portion P22, portion P13 and portion P23) are set such that both are bonded or both are not bonded. That is, when only one of the pair of portions is bonded with the adhesive, the support of drive element 1 with respect to substrate 2 becomes unbalanced with rotation axis R0 interposed therebetween, and thus, there is a concern that the resonance driving of movable part 11 becomes unstable. Thus, to stably resonantly drive movable part 11, it is preferable that both of the portions constituting a pair symmetrical with respect to rotation axis R0 are bonded to substrate 2 or both of the portions are not bonded to substrate 2.

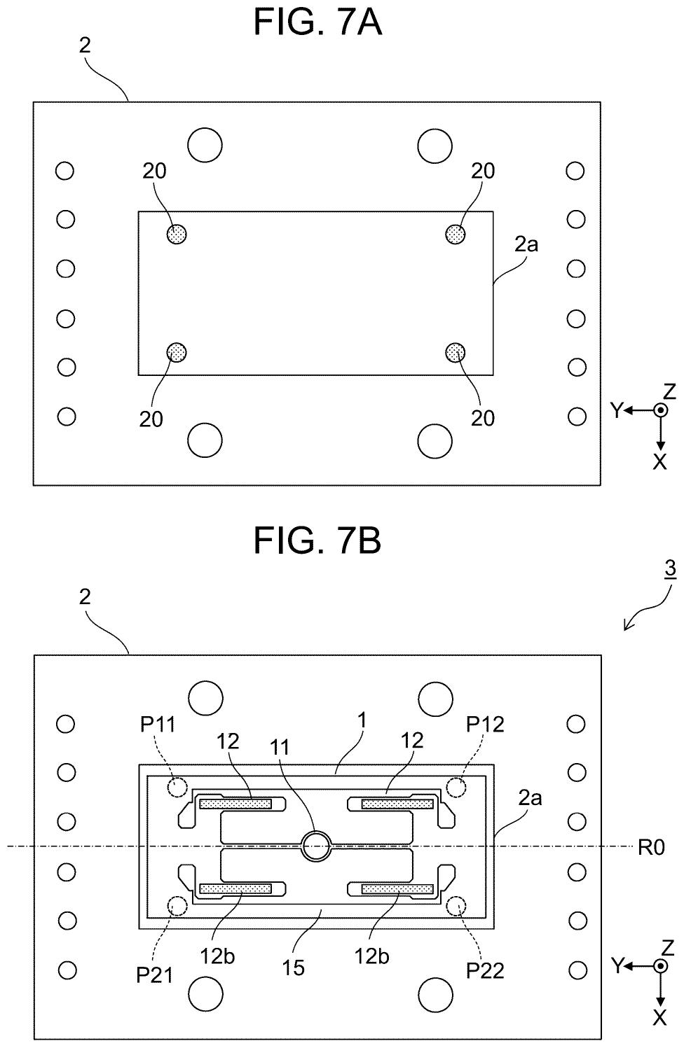

FIGS. 7A and 7B are plan views illustrating a method for bonding drive element 1 to substrate 2.

In this bonding method, among six antinode portions P11 to P13 and P21 to P23 illustrated in FIG. 6, adhesive 20 is applied to portions P11, P12, P21, and P22, and drive element 1 is bonded to recess 2a of substrate 2. That is, as illustrated in FIG. 7A, adhesive 20 is applied to the four corners of recess 2a corresponding to portions P11, P12, P21, and P22, and then, as illustrated in FIG. 7B, drive element 1 is installed in recess 2a. Thus, drive element 1 is bonded to substrate 2, and vibration module 3 is configured. Instead of applying adhesive 20 to recess 2a, adhesive 20 may be applied to fixing part 15 side to perform bonding.

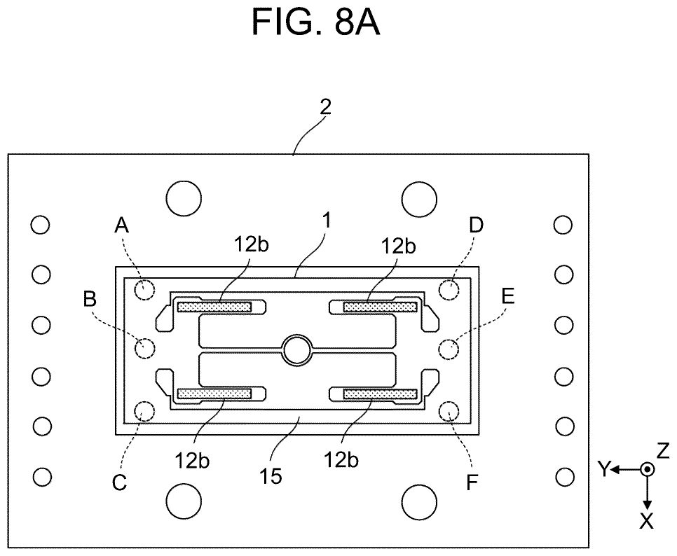

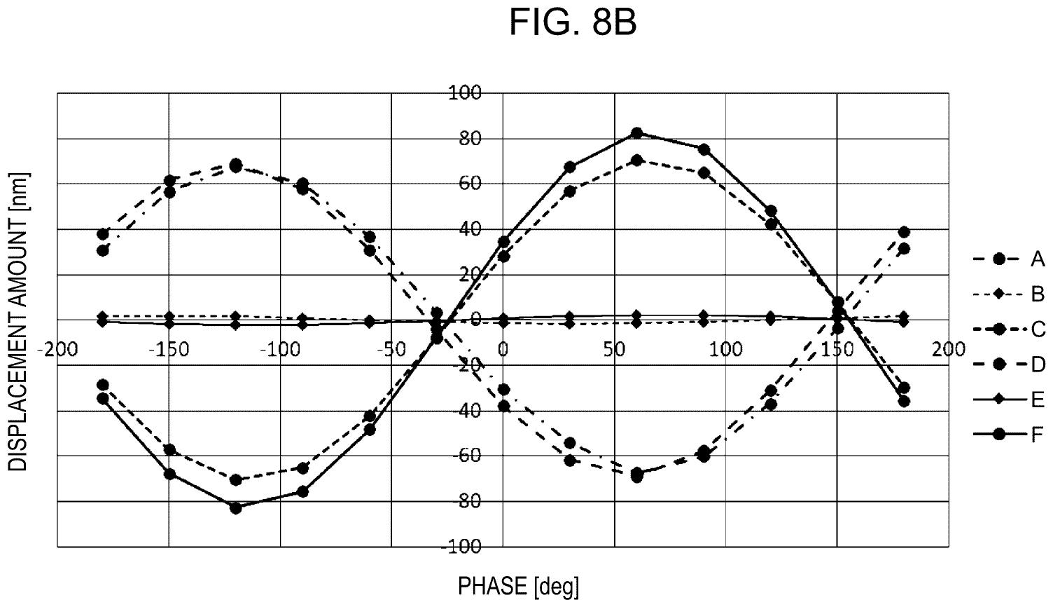

FIG. 8A is a diagram illustrating a measurement position when drive element 1 bonded by bonding method in FIGS. 7A and 7B is actually resonantly driven. FIG. 8B is a diagram illustrating a verification example in which the vibration generated in fixing part 15 in Z-axis directions is measured when drive element 1 bonded by the bonding method illustrated in FIGS. 7A and 7B is actually resonantly driven. In FIG. 8B, “deg” represents the degree (°) of the angle. That is, 1 deg=1°.

Here, drive element 1 was driven resonantly at around 55 kHz. The AC voltage applied to piezoelectric body 12b was set to about 5 V. The vibration was measured at six positions A to F in FIG. 8A under a normal temperature environment. The thickness of adhesive 20 was set to about 1 m.

FIG. 8B is a graph illustrating the measurement results.

In FIG. 8B, the horizontal axis represents the phase of one cycle of vibration, and the vertical axis represents the displacement amount of each part in the Z-axis directions. As illustrated in FIG. 8B, at positions A, C, D, and F close to the portions corresponding to antinodes of vibration, vibration of about 60 nm to 80 nm was measured. On the other hand, at positions B and E corresponding to nodes of vibration, vibration hardly occurred.

To appropriately reduce the Q factor of vibration module 3 at the time of resonance driving, it is necessary to appropriately vibrate the portions corresponding to antinodes of vibration of fixing part 15 bonded by adhesive 20 in a temperature range assumed in the use environment of vibration module 3. In the measurement results of FIG. 8B, the Q factor of vibration module 3 can be appropriately reduced by vibrating the portions corresponding to antinodes of vibration of fixing part 15 bonded by adhesive 20 at a vibration displacement (amplitude) of about 60 nm to 80 nm under the normal temperature environment.

For example, when the temperature range assumed in the use environment is 0° C. to 50° C., the elastic modulus of adhesive 20 is smaller than that at the normal temperature in the vicinity of 50° C. Thus, the vibration of the portions corresponding to antinodes of vibration of fixing part 15 bonded by adhesive 20 is larger than that in the case of FIG. 8B. Conversely, since the elastic modulus of adhesive 20 is larger than that at the normal temperature in the vicinity of 0° C., the vibration of the portions corresponding to antinodes of vibration of fixing part 15 bonded by adhesive 20 is smaller than that in the case of FIG. 8B.

In addition, when vibration module 3 (optical deflector) is mounted on AR glasses 4 illustrated in FIG. 4, the voltage applied to piezoelectric body 12b is increased to about 10 V to obtain a larger swing angle. In this case, when the temperature range assumed in the use environment is from 0° C. to 50° C. inclusive, even when the environmental temperature is 0° C., the vibration displacement (amplitude) of the portions corresponding to antinodes of vibration of fixing part 15 bonded by adhesive 20 is about 50 nm.

Thus, when the portion corresponding to an antinode of vibration of fixing part 15 fixed by adhesive 20 is more than or equal to 50 nm in this temperature range at the time of resonance driving, the antinode portion can be appropriately vibrated, and the Q factor of vibration module 3 can be appropriately reduced. Accordingly, the influence of the static displacement of piezoelectric body 12b at the time of resonance driving can be appropriately suppressed.

The thickness of adhesive 20 needs to be set to a thickness necessary for appropriately generating vibration that can occur in the portion corresponding to an antinode of vibration of fixing part 15 bonded by adhesive 20 in an assumed temperature range. For example, the thickness of adhesive 20 is preferably set to about more than or equal to 100 times the maximum vibration displacement (maximum amplitude) to be generated in the portion corresponding to an antinode of vibration of fixing part 15 bonded by adhesive 20 in an assumed temperature range.

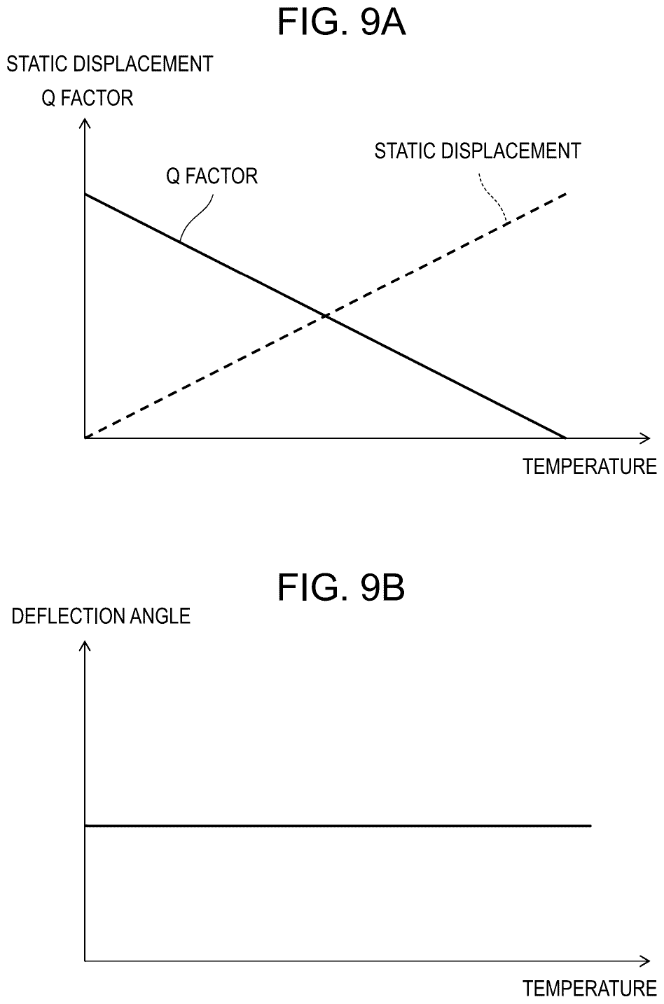

FIG. 9A is a graph schematically illustrating an ideal relationship between a change in static displacement of vibration module 3 associated with a temperature change and a change in the Q factor of vibration module 3 associated with the temperature change.

As illustrated in FIG. 9A, ideally, the Q factor of vibration module 3 may change such that a value obtained by multiplying the magnitude of the static displacement and the Q factor at each temperature becomes substantially constant at all temperatures in the temperature range. This can maintain the output characteristic of vibration module 3 substantially constant regardless of the temperature change. As a result, as illustrated in FIG. 9B, the deflection angle of movable part 11 and reflective surface 11a at the time of resonance driving can be kept substantially constant regardless of the temperature change.

In other words, the type (temperature characteristic) of adhesive 20 and the thickness of adhesive 20 may be adjusted so as to obtain such a change in the Q factor in relation to the change in the static displacement associated with the temperature change. With this configuration, the influence of the static displacement associated with the temperature change on the resonance driving of movable part 11 can be offset by the change in the Q factor according to the temperature of vibration module 3 because of adhesive 20. As a result, the deflection angle of movable part 11 and reflective surface 11a at the time of resonance driving can be kept substantially constant regardless of the temperature change.

### Effect of Exemplary Embodiment

According to the above-described exemplary embodiment, the following effects may be exhibited.

As illustrated in FIGS. 7A and 7B, fixing part 15 is bonded to recess 2a of substrate 2 by adhesive 20 whose elastic modulus decreases as the temperature rises in the plurality of portions P11, P12, P21, and P22 which are discrete from each other, and the plurality of portions P11, P12, P21, and P22 are four of portions P11 to P13 and P21 to P23 corresponding to antinodes of vibration generated in fixing part 15 when movable part 11 is driven as illustrated in FIG. 6.

According to this configuration, the elastic modulus of adhesive 20 decreases as the temperature rises. Thus, the portions corresponding to antinodes of vibration of fixing part 15 bonded by adhesive 20 easily vibrate as the temperature rises. Thus, as the temperature rises, the loss of vibration energy in the portions corresponding to antinodes of vibration increases, and the Q factor as vibration module 3 decreases. As a result, the increase in the static displacement and the decrease in the Q factor associated with the temperature rise act in opposite directions to each other, and as a result, the output of the vibration module is suppressed from changing with the temperature change. Therefore, it is possible to suppress a change in the deflection angle of the movable part based on a temperature change.

As illustrated in FIGS. 7A and 7B, the plurality of portions P11, P12, P21, and P22 of fixing part 15 discretely bonded to substrate 2 with adhesive 20 are all portions corresponding to antinodes of vibration generated in fixing part 15 at the time of resonance drive. Thus, the portions corresponding to antinodes of vibration bonded by adhesive 20 can smoothly vibrate without being limited by other fixing parts. Thus, the vibration energy can be smoothly lost in the portions corresponding to antinodes of vibration bonded by adhesive 20, and the Q factor of vibration module 3 can be appropriately reduced as the temperature changes. Therefore, the influence of the static displacement associated with the temperature change on the resonance driving can be appropriately suppressed.

As illustrated in FIGS. 7A and 7B, the plurality of portions of fixing part 15 bonded by adhesive 20 include an even number of portions P11, P12, P21, and P22 corresponding to antinodes of vibration, and the even number of portions P11, P12, P21, and P22 corresponding to antinodes of vibrations form a pair (portion P11 and portion P21, portion P12 and portion P22) symmetrical with respect to rotation axis R0. Thus, drive element 1 is supported on substrate 2 in a well-balanced manner in a direction perpendicular to rotation axis R0. Thus, movable part 11 can be resonantly driven stably.

As illustrated in FIGS. 7A and 7B, fixing part 15 has a rectangular frame shape in plan view, and the plurality of portions bonded by adhesive 20 include portions P11, P12, P21, and P22 corresponding to antinodes of vibration near the four corners of the frame shape. By bonding the portions near the four corners of the rectangle in this manner, fixing part 15 can be stably supported on substrate 2.

The vibration displacement at the time of resonance driving in the portions corresponding to antinodes of vibration fixed by adhesive 20 is preferably set to more than or equal to 50 nm in a predetermined temperature range (from 0° C. to 50° C. inclusive). With this configuration, as described with reference to FIG. 8B, at a predetermined temperature within this temperature range, vibration according to the elastic modulus of adhesive 20 can be generated in the portions corresponding to antinodes of vibration of fixing part 15. Thus, the Q factor of vibration module 3 can be appropriately changed as the temperature changes, and the change in the deflection angle of movable part 11 based on the temperature change can be appropriately suppressed.

Here, the above-described predetermined temperature range can be set to from 0° C. to 50° C. inclusive. As a result, for example, in a temperature range assumed in a daily use environment of AR glasses 4 or the like, the Q factor of vibration module 3 can be appropriately changed as the temperature changes, and a change in the deflection angle of the movable part based on the temperature change can be appropriately suppressed. Thus, it is possible to cause vibration module 3 to perform an operation suitable for a daily use environment.

As illustrated in FIG. 1, drive unit 12 is a tuning fork vibrator. With this configuration, movable part 11 can be smoothly and repeatedly rotated (resonantly driven) about rotation axis R0.

As illustrated in FIG. 1, two tuning fork vibrators (drive unit 12) are disposed in opposite directions along rotation axis R0. With this configuration, movable part 11 can be stably driven with a larger torque.

### Modifications

The configuration example of the present disclosure is not limited to the exemplary embodiment described above, and various modifications can be made.

For example, in the exemplary embodiment described above, among the plurality of portions P11 to P13 and P21 to P23 corresponding to antinodes of vibration generated in fixing part 15 when movable part 11 is resonantly driven, four portions P11, P12, P21, and P22 near the four corners of fixing part 15 are bonded to substrate 2 with adhesive 20, but the portions to which fixing part 15 of substrate 2 is bonded are not limited to this example.

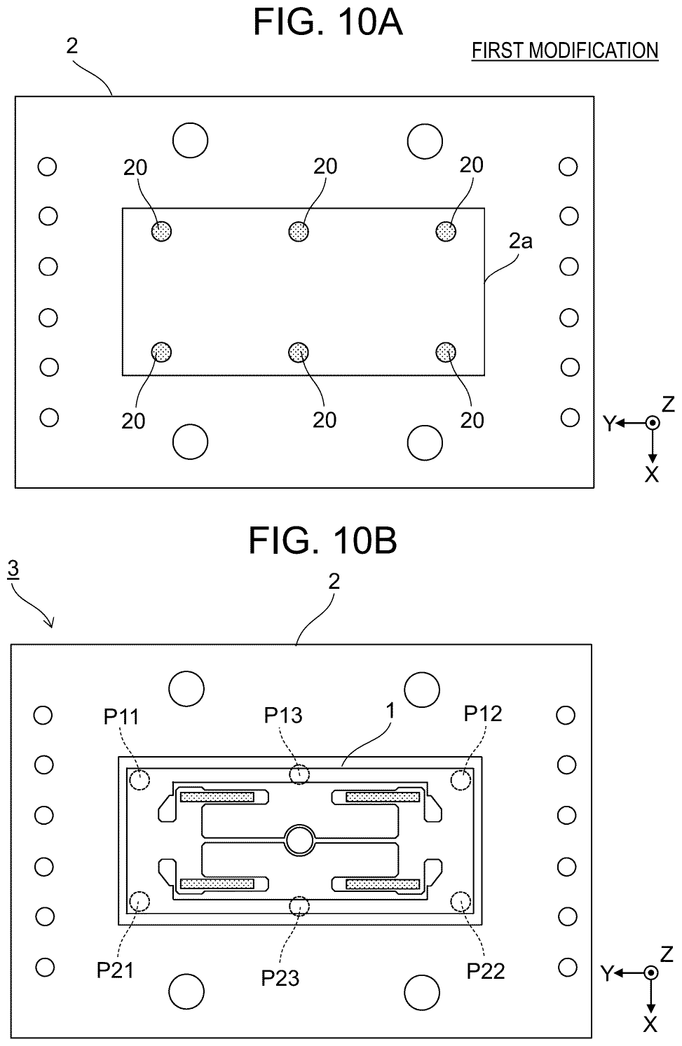

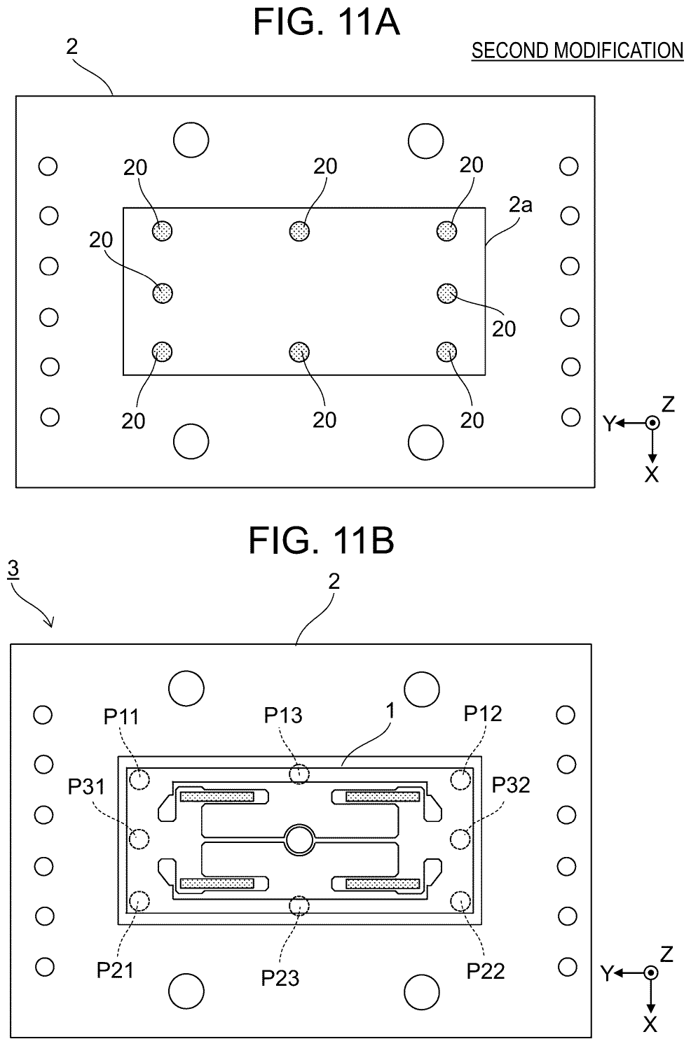

A first modification of the method for bonding drive element 1 to substrate 2 is illustrated in plan views of FIGS. 10A and 10B. A second modification of the method for bonding drive element 1 to substrate 2 is illustrated in plan views of FIGS. 11A and 11B.

For example, as in the first modification of FIGS. 10A and 10B, all of portions P11 to P13 and P21 to P23 corresponding to antinodes of vibration may be bonded by adhesive 20. In this case, as illustrated in FIG. 10A, adhesive 20 is applied to the portions of recess 2a corresponding to portions P11 to P13 and P21 to P23 corresponding to antinodes of vibration, and then, as illustrated in FIG. 10B, drive element 1 is installed in recess 2a. Thus, drive element 1 is bonded to substrate 2, and vibration module 3 is configured.

Alternatively, as in the second modification of FIGS. 11A and 11B, portions P31 and P32 corresponding to nodes of vibration may be further bonded by adhesive 20 together with portions P11 to P13 and P21 to P23 corresponding to antinodes of vibration. In this case, as illustrated in FIG. 11A, adhesive 20 is applied to the portions of recess 2a corresponding to portions P11 to P13 and P21 to P23 corresponding to antinodes of vibration and portion P32 corresponding to a node of vibration, and then, as illustrated in FIG. 11B, drive element 1 is installed in recess 2a. Thus, drive element 1 is bonded to substrate 2, and vibration module 3 is configured.

Also in these cases, as in the case of FIGS. 7A and 7B, instead of applying adhesive 20 to recess 2a, adhesive 20 may be applied to fixing part 15 side to perform bonding.

In the bonding method of FIGS. 11A and 11B, the bonding strength of drive element 1 can be enhanced as compared with the case of FIGS. 10A and 10B. However, since portions P31 and P32 corresponding to nodes of vibration near portions P11, P12, P21, and P22 corresponding to antinodes of vibration bonded with adhesive 20 are bonded, portions P11, P12, P21, and P22 corresponding to antinodes of vibration are likely to be limited by the bonding of portions P31 and P32 corresponding to nodes of vibration.

Thus, to more stably vibrate the antinode portions as the temperature changes and appropriately control the Q factor of vibration module 3, it is preferable that only the portions corresponding to antinodes of vibration of fixing part 15 are discretely bonded to substrate 2 with adhesive 20 as in the exemplary embodiment and the modifications described above.

In the exemplary embodiment, recess 2a for installing drive element 1 is provided in substrate 2, but recess 2a does not have to be provided in substrate 2. For example, fixing part 15 of drive element 1 may be bonded to the upper surface of a plate-like substrate with adhesive 20 by the method described above.

Substrate 2 is preferably made of a material whose elastic modulus decreases as the temperature rises. With this configuration, the Q value of vibration module 3 can be more favorably reduced as the temperature rises. Examples of such a material include a glass epoxy substrate and a ceramic substrate.

In the exemplary embodiment, two drive units 12 are disposed in opposite directions along rotation axis R0, but one of two drive units 12 may be omitted.

In the exemplary embodiment, drive unit 12 is a tuning fork vibrator, but drive unit 12 may be a vibrator of another type that is resonantly driven. For example, drive unit 12 may be made up of a meander vibrator that is resonantly driven.

In the exemplary embodiment, the shape of movable part 11 is circular, but the shape of movable part 11 may be another shape such as a square. The shape of drive element 1 in plan view and the dimensions of each part of drive element 1 can also be changed as appropriate.

In addition, drive element 1 may be used as an element other than an optical deflector. When drive element 1 is used as an element other than an optical deflector, reflective surface 11a does not have to be disposed in movable part 11, and another member other than reflective surface 11a may be disposed.

In addition, various modifications can be appropriately made to the exemplary embodiments of the present disclosure within the scope of the technical idea disclosed in the claims.

### (Supplementary Note)

Technologies noted below are disclosed by the description of the exemplary embodiments.

### (Technology 1)

A vibration module including:
a drive element;
a substrate supporting the drive element,
wherein
the drive element includes:
a movable part;
a drive unit that includes a piezoelectric body as a drive source and rotates the movable part about a rotation axis; and
a fixing part that supports the movable part and the drive unit and is bonded to the substrate,
the fixing part is bonded to the substrate at a plurality of portions discrete from each other with an adhesive whose elastic modulus decreases as a temperature rises, and
the plurality of portions include a portion corresponding to an antinode of vibration generated in the fixing part when the movable part is resonantly driven.

According to this technology, the elastic modulus of the adhesive decreases as the temperature rises. Thus, the portions corresponding to antinodes of vibration of the fixing part bonded by the adhesive easily vibrate as the temperature rises. Thus, as the temperature rises, the loss of vibration energy in the portions corresponding to antinodes of vibration increases, and the Q factor as the vibration module decreases. As a result, the increase in the static displacement and the decrease in the Q factor associated with the temperature rise act in opposite directions to each other, and as a result, the output of the vibration module is suppressed from changing with the temperature change. Therefore, it is possible to suppress a change in the deflection angle of the movable part based on a temperature change.

### (Technology 2)

The vibration module according to Technology 1,
wherein each of the plurality of portions is a portion corresponding to the antinode of vibration.

According to this technology, the portions corresponding to antinodes of vibration bonded by the adhesive can smoothly vibrate without being limited by other fixing parts. Thus, the vibration energy can be smoothly lost in the portions corresponding to antinodes of vibration bonded by the adhesive, and the Q factor of the vibration module can be appropriately reduced as the temperature changes. Therefore, the influence of the static displacement associated with the temperature change on the resonance driving can be appropriately suppressed.

### (Technology 3)

The vibration module according to Technology 1 or 2, wherein
the plurality of portions include an even number of the portions corresponding to antinodes of vibration, and
the even number of portions corresponding to the antinodes of vibration constitute a pair symmetrical with respect to the rotation axis.

According to this technology, the drive element is supported on the substrate in a well-balanced manner in a direction perpendicular to the rotation axis. Thus, the movable part can be resonantly driven stably.

### (Technology 4)

The vibration module according to any one of Technologies 1 to 3, wherein
the fixing part has a rectangular frame shape in plan view, and
the plurality of portions include the portion corresponding to the antinode of vibration near four corners of the rectangular frame shape.

According to this technology, by bonding the portions near the four corners of the rectangle, the fixing part can be stably supported on the substrate.

### (Technology 5)

The vibration module according to any one of Technologies 1 to 4,
wherein the portion of the antinode fixed with the adhesive has a vibration displacement at a time of resonance driving of more than or equal to 50 nm in a predetermined temperature range.

According to this technology, at a predetermined temperature within this temperature range, vibration according to the elastic modulus of the adhesive can be generated in the portions corresponding to antinodes of vibration of the fixing part. Thus, the Q factor of the vibration module can be appropriately changed as the temperature changes, and the change in the deflection angle of the movable part based on the temperature change can be appropriately suppressed.

### (Technology 6)

The vibration module according to Technology 5,
wherein the predetermined temperature range is from 0° C. to 50° C. inclusive.

According to this technology, for example, in a temperature range assumed in a daily use environment of AR glasses or the like, the Q factor of the vibration module can be appropriately changed as the temperature changes, and a change in the deflection angle of the movable part based on the temperature change can be appropriately suppressed. Thus, it is possible to cause the vibration module to perform an operation suitable for a daily use environment.

### (Technology 7)

The vibration module according to any one of Technologies 1 to 6,
wherein the drive unit is a tuning fork vibrator.

According to this technology, the movable part can be smoothly and repeatedly rotated (resonantly driven) about the rotation axis.

### (Technology 8)

The vibration module according to Technology 7,
wherein two tuning fork vibrators each being the turning fork vibrator are disposed in opposite directions along the rotation axis.

According to this technology, the movable part can be stably driven with a larger torque.

### (Technology 9)

An optical deflector including:
the vibration module according to any one of Technologies 1 to 8; and
a reflective surface disposed on the movable part.

According to this technology, because the vibration module according to any one of Technologies 1 to 8 is included, it is possible to suppress a change in deflection angle of the movable part and the reflective surface based on a temperature change. Thus, the light entering the reflective surface can be stably deflected at a predetermined deflection angle, and scanning with the light can be performed at the predetermined deflection angle.

The vibration module and the optical deflector of the present disclosure can suppress a change in deflection angle of a movable part due to a change in static displacement of a piezoelectric body based on a temperature change. Thus, the vibration module and the optical deflector of the present disclosure are industrially useful.

What is claimed is:

1. A vibration module comprising:
a drive element;
a substrate supporting the drive element,
wherein
the drive element includes:
a movable part;
a drive unit that includes a piezoelectric body as a drive source and rotates the movable part about a rotation axis; and
a fixing part that supports the movable part and the drive unit and is bonded to the substrate,
the fixing part is bonded to the substrate at a plurality of portions discrete from each other with an adhesive whose elastic modulus decreases as a temperature rises, and
the plurality of portions include a portion corresponding to an antinode of vibration generated in the fixing part when the movable part is resonantly driven.

2. The vibration module according to claim 1,
wherein each of the plurality of portions is a portion corresponding to the antinode of vibration.

3. The vibration module according to claim 1, wherein
the plurality of portions include an even number of the portions corresponding to antinodes of vibration, and
the even number of portions corresponding to the antinodes of vibration constitute a pair symmetrical with respect to the rotation axis.

4. The vibration module according to claim 1, wherein
the fixing part has a rectangular frame shape in plan view, and
the plurality of portions include the portion corresponding to the antinode of vibration near four corners of the rectangular frame shape.

5. The vibration module according to claim 1,
wherein the portion of the antinode fixed with the adhesive has a vibration displacement at a time of resonance driving of more than or equal to 50 nm in a predetermined temperature range.

6. The vibration module according to claim 5,
wherein the predetermined temperature range is from 0° C. to 50° C. inclusive.

7. The vibration module according to claim 1,
wherein the drive unit is a tuning fork vibrator.

8. The vibration module according to claim 7,
wherein two tuning fork vibrators each being the turning fork vibrator are disposed in opposite directions along the rotation axis.

9. An optical deflector comprising:
the vibration module according to claim 1; and
a reflective surface disposed on the movable part.
